(19) United States
(12) Patent Application Publication
(10) Pub. No.: US 2010/0038060 A1
(43) Pub. Date: Feb. 18, 2010

(54) HEAT DISSIPATION DEVICE CAPABLE OF COLLECTING AIR

(75) Inventor: CHING-HANG SHEN, Kaohsiung (TW)

Correspondence Address: G. LINK CO., LTD, 3550 BELL ROAD, MINOOKA, IL, 60447, US

(73) Assignee: ASIA VITAL COMPONENTS CO., LTD., Kaohsiung (TW)

(21) Appl. No.: 12/193,056

(22) Filed: Aug. 18, 2008

(51) Int. Cl. F28D 15/00; H05K 7/20

(52) U.S. Cl. 165/104.34; 165/120; 361/697

(57) ABSTRACT

A heat dissipation device capable of collecting air includes a fan, a heat sink and an air collecting hood. The top of the heat sink is joined to the fan. The air collecting hood is disposed to surround the heat sink. It is characterized in that the air collecting hood has an air inlet, a middle section and an air outlet; and the inner side of the middle section has a plurality of support projections against the periphery of said heat sink. Therefore, the air induced by the fan can be gathered at the surroundings of the heat sink with the air collecting hood for enhancing the effect of the heat dissipation.

### BACKGROUND OF THE INVENTION

1. Field of the Invention

The present invention is related to a heat dissipation device capable of collecting air and particularly to a heat dissipation device, which provides an air collecting hood capable of collecting the air induced by the fan for enhancing the effect of cooling the central processing unit (CPU) in a computer or the like.

2. Brief Description of the Related Art

The current way for dissipating the heat emitted from the running CPU is by means of a heat sink being placed on top of the CPU for conducting the heat with a fan attached to the heat sink to intensify the heat exchange of the convection and control the temperature reduction of the CPU.

However, the preceding way for decreasing the temperature of the CPU has low heat transfer efficiency. The air induced by the fan A of the prior art flows from one side to another side as shown in FIG. 1. Further, the heat sink B is stacked to the CPU and the fan A is stacked to the heat sink B respectively. It can be seen that there is no air passage at the central area of the fan due to the motor of the fan being disposed at the central area such that the air flow is forced with the fan A to move toward the heat sink B first and leave the heat sink B afterward rapidly. As a result, most of the air flow is incapable of passing through the heat sink B to carry the heat therein outward and it is the reason why the entire heat dissipation effect of the heat dissipation device is always undesirable.

### SUMMARY OF THE INVENTION

The main object of the present invention is to provide a heat dissipation device capable of gathering the air flow and enhancing the heat dissipation effect.

In order to achieve the object, a heat dissipation device capable of collecting air according to the present invention includes a fan, a heat sink and an air collecting hood. The top of the heat sink is joined to the fan. The air collecting hood is disposed to surround the heat sink. It is characterized in that the air collecting hood has an air inlet, a middle section and an air outlet; and the inner side of the middle section has a plurality of support projections against the periphery of said heat sink. Therefore, the air flow induced by the fan can be gathered at the surroundings of the heat sink with the air collecting hood for enhancing the effect of the heat dissipation.

Further, the air collecting hood according to the present invention has the air inlet larger than the air outlet to form a shape of funnel for the air flow being gathered effectively.

### BRIEF DESCRIPTION OF THE DRAWINGS

The detail structure, the applied principle, the function and the effectiveness of the present invention can be more fully understood with reference to the following description and accompanying drawings, in which:

FIG. 1 is a plan view of the conventional heat dissipation device;

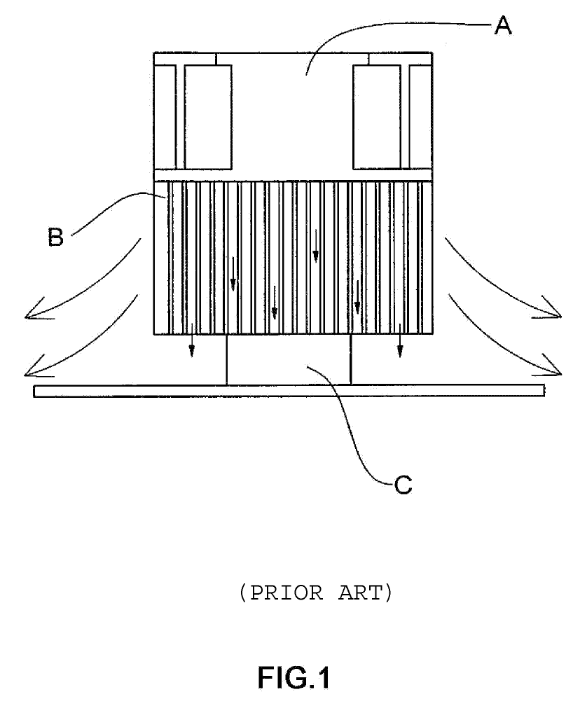

FIG. 2 is a perspective view of an air collecting hood for a heat dissipation device according to the present invention;

FIG. 3 is a disassembled perspective view of an air collecting hood and the heat dissipation device according to the present invention; and

FIG. 4 is a sectional view of the heat dissipation device with an air collecting hood according to the present invention.

### DETAILED DESCRIPTION OF THE INVENTION

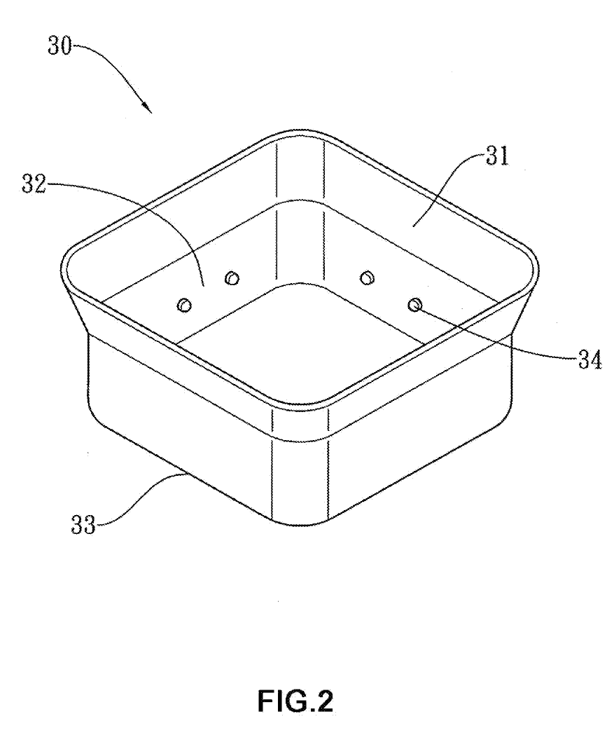

Referring to FIG. 2, a heat dissipation device capable of collecting air according to the present invention comprises a fan 10, a heat sink 20 and an air collecting hood 30. The air collecting hood 30 has an air inlet 31, a middle section 32 and an air outlet 33. The air inlet 31 is an opening larger than the air outlet 33 such that the air collecting hood 30 has a shape similar to a funnel. The inner side of the middle section 32 has a plurality of support projections 34 for contacting the periphery of the heat sink 20 such that a gap 35 is formed between the middle section 32 and the heat sink 20 for the outward air being capable of flowing toward the heat sink 20 and the heat source 40 through the gap 35 after being collected by the air collecting hood 30. In this way, the heat dissipation can be enhanced more effectively.

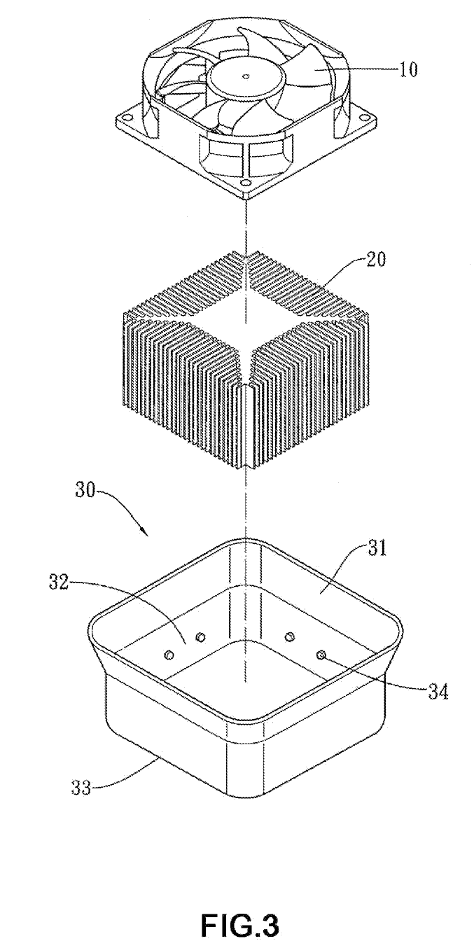

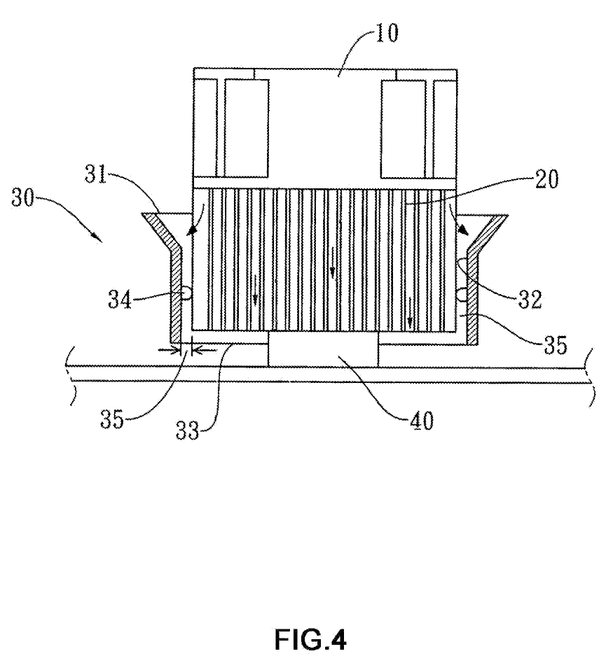

Referring to FIGS. 3 and 4, it can be seen that the heat sink 20 is placed in the air collating hood 30 in a way of the periphery of the heat sink 20 being disposed against the support projections 34. The top of the heat sink 20 is joined to the fan 10 and the bottom of the heat sink 20 is placed on the heat source 40 in a way of the air outlet 33 and main board having a small space in between instead of covering the heat source 40.

When the air is induced to flow toward the heat sink 20 and hits the heat sink 20, the air scatters to the surroundings and the air collecting hood 30 gathers and guides the scattered air to pass through the heat sink and the heat source for obtaining a better effect of heat dissipation.

Besides, the air outlet 33 of the air collecting hood 30 can be provided with a converging shape (not sown) to allow the air reaching the heat source 40 effectively for enhancing the heat dissipation.

While the invention has been described with referencing to the preferred embodiment thereof, it is to be understood that modifications or variations may be easily made without departing from the spirit of this invention, which is defined by the appended claims.

What is claimed is:

1. A heat dissipation device capable of collecting air comprising:
a fan;
a heat sink with a top thereof being joined to said fan; and
an air collecting hood being disposed to surrounding said heat sink and having a first side and second side opposite to each other;
characterized in that said air collecting hood has an air inlet, which is disposed at said first side, a middle section and an air outlet, which is disposed at said second side; the inner side of said middle section has a plurality of support projections against the periphery of said heat sink.

2. The heat dissipation device capable of collecting air as defined in claim 1, wherein said air collecting hood has shape similar to a funnel.

3. The heat dissipation device capable of collecting air as defined in claim 1, wherein said air inlet provides an opening greater than that of said air outlet.

4. The heat dissipation device capable of collecting air as defined in claim 1, wherein said air outlet has a shape of converging to form a guide opening.
